(19) United States
(12) Patent Application Publication
(10) Pub. No.: US 2012/0138986 A1
(43) Pub. Date: Jun. 7, 2012

(54) METHOD FOR FABRICATION OF (AL,IN,GA) NITRIDE BASED VERTICAL LIGHT EMITTING DIODES WITH ENHANCED CURRENT SPREADING OF N-TYPE ELECTRODE

(75) Inventors: ROY B. CHUNG, Carlsbad, CA (US); HUNG TSE CHEN, GOLETA, CA (US); CHIH-CHIEN PAN, GOLETA, CA (US); JAMES S. SPECK, GOLETA, CA (US); STEVEN P. DENBAARS, GOLETA, CA (US); SHUJI NAKAMURA, SANTA BARBARA, CA (US)

(73) Assignee: THE REGENTS OF THE UNIVERSITY OF CALIFORNIA, Oakland, CA (US)

(21) Appl. No.: 13/284,001

(22) Filed: Oct. 28, 2011

Related U.S. Application Data
(60) Provisional application No. 61/407,782, filed on Oct. 28, 2010.

(51) Int. Cl. H01L 33/22

(52) U.S. Cl. 257/98; 438/29; 257/E33.066

(57) ABSTRACT

A method of fabricating an (Al, In, Ga)N based optoelectronic device, comprising forming an n-type ohmic contact on an (Al, In, Ga)N surface of the device, wherein the surface comprises an Nitrogen face (N-face) and a N-rich face of the (Al, In, Ga)N, the n-type contact is on the N-face and the N-rich face, and the current spreading of the n-type ohmic contact is enhanced by a combination of a lower and a higher contact resistance on the surface.

### CROSS REFERENCE TO RELATED APPLICATIONS

This application claims the benefit under 35 U.S.C. Section 119(e) of co-pending and commonly-assigned U.S. Provisional Application Ser. No. 61/407,782 filed on Oct. 28, 2010, by Roy B. Chung, Hung Tse Chen, Chih-Chien Pan, James S. Speck, Steven P. DenBaars, and Shuji Nakamura, entitled “METHOD FOR FABRICATION OF (AL, IN, GA) NITRIDE BASED VERTICAL LIGHT EMITTING DIODES WITH ENHANCED CURRENT SPREADING OF N-TYPE ELECTRODE,” attorney's docket number 30794.400-US-P1 (2011-231-1), which application is incorporated by reference herein.

### BACKGROUND OF THE INVENTION

1. Field of the Invention

The present invention relates generally to enhanced current spreading in n-type electrodes of semiconductor devices.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Conventional (Al, In, Ga)N based optoelectronic devices are typically grown by metal organic chemical vapor deposition (MOCVD), or molecular beam epitaxy (MBE), using a foreign substrate such as a sapphire and SiC due to the lack of native substrates. Since the first demonstration of commercially feasible blue light emitting diodes (LEDs), grown on a sapphire substrate by Nakamura et al. [1], extensive research has been done over a decade, and the performance of the blue LEDs has been dramatically improved.

Typical c-plane Light Emitting Diodes (LEDs) on a foreign substrate are lateral device structures 100, in which p-contact (e.g., transparent p-type electrode such as Indium Tin Oxide, ITO 102) and n-contact (e.g., ohmic contact 104) are in lateral configuration, as shown in FIG. 1. As indicated by the arrows 106 within the structure 100 in FIG. 1, the current path can be longer for a lateral structure, increasing the serial dynamic resistance. This structure also requires a transparent current spreading (TCS) p-type electrode 102 in order to minimize the absorption from the p-type electrode 102. Tin doped indium oxide (ITO) has been the most common TCS electrode 102, but its transparency is still not at 100%, and the contact resistance is also an issue for the oxides. The low thermal conductivity (35 W/m-K) of the sapphire substrate 108 also makes it difficult for the thermal management under high current operation conditions. Also shown in FIG. 1 are the active region 110 between n-type GaN 112 and p-type GaN 114, and bonding pad 116.

One method to overcome this problem is to fabricate vertical c-plane LEDs, as shown in FIGS. 2(a)-(b). FIGS. 2(a)-(b) schematically shows the vertical LEDs are formed by a process of the laser lift-off (LLO). The process comprises (b) separating the LED epitaxial layer (LED epi 200), grown by MOCVD, from a substrate 202, after (a) illuminating a backside of the sapphire substrate using laser 204 illumination 206 with a wavelength that is transparent to the substrate 202 (e.g., sapphire substrate such as (0001) sapphire substrate) but is significantly absorbed by GaN at the GaN/sapphire interface 208. The surface 210 of the LED epi 200 that is exposed after removal of the substrate 202 is an exposed Nitrogen face (N-face).

FIG. 3 illustrates a vertical c-plane LED 300 fabricated using the method of FIG. 2, wherein the LED epi 200 comprises an active region 302, n-type GaN 304, and p-type GaN 306, and the LED epi 200 is attached to a metal reflector 308 on one side. An n-type electrode 310 contacts the n-type GaN 304. The arrows 312 within the structure 300 indicate the current path from n-type GaN 304 to p-GaN 306.

Due to the nature of the wurtzite crystal structure, GaN shows a Ga-face along the (+) c-direction, and N-face along the opposite direction, which results in non-zero polarity in the material. Therefore, the exposed backside 210 of LEDs grown on a c-plane sapphire by the LLO process, is N-face. However, a high quality ohmic contact on the N-face GaN is difficult to achieve due to the polarization field dependence of the electrical characteristics.

An aluminum (Al)-based metal contact on the Ga-face GaN surface could form AlN after thermal annealing, which would create a two dimensional electron gas (2DEG) at the interface, and a low contact resistance is achieved by this 2DEG and N-vacancies [2].

A Ti/Au based metal electrode on the N-face was studied by Kwak et al., and it was reported that an annealing temperature above 600° C. was required to achieve the ohmic contact [3].

For N-face GaN prepared by LLO, thermal degradation above 400° C. was reported by Kim et al. [4].

### SUMMARY OF THE INVENTION

The present invention describes a fabrication method to improve the current spreading for an n-type electrode on a nitrogen face or N-face-like GaN surface. Current spreading is enhanced by forming two regions with different contact resistances. The current flows from the high contact resistance side to the lower contact resistance side. With a proper electrode design, the current spreading is more efficient without covering more areas with the metal contacts.

The present invention describes a method of fabricating a III-nitride based optoelectronic or electronic device, comprising forming one or more n-type ohmic contacts to a surface of an n-type III-nitride layer in a device, wherein the device is III-nitride based, the surface is a III-nitride surface, the surface includes at least a roughened portion, and the roughened portion is a roughened Nitrogen rich (N-rich) face of the III-nitride surface.

The surface can include the roughened portion and at least a non-roughened (planar) portion, the non-roughened portion can be an N-rich face of the III-nitride surface, and the n-type ohmic contacts can be formed on both the roughened portion and the non-roughened portion, and a contact resistance can be lower for the n-type ohmic contact on the roughened portion as compared to a contact resistance for the n-type ohmic contact on the non-roughened portion.

The roughened portion can be roughened such that a current spreading in the n-type layer is increased, and such that a contact resistance for the n-type ohmic contact on the roughened portion is reduced (e.g., reduced to 1×10⁻³ ohm centimeters squared or less, or reduced to a value less than or equal to a contact resistance for an n-type ohmic contact on a Gallium face (Ga-face) of a similar III-nitride layer).

The device can be a light emitting device, such as a vertical light emitting diode, for emitting light, wherein the light's emission is uniform, with no significant increase in the emission at one or more locations for injecting drive current into the device. The emission can be uniform for drive currents of 500 milliamps or greater, or 1 amp or greater, for example.

The N-rich face can be a semipolar plane of the III-nitride layer comprising at least as much nitrogen as a group III element. For example, the semipolar plane can be a (10-12), (11-22), or (10-11) semi-polar plane. The N-rich face can be a Nitrogen-face of the III-nitride layer.

The roughened portion can be roughened by a photoelectrochemical etching or dry etching technique.

The n-type ohmic contacts can comprise metal, an annealing temperature of the n-type ohmic contacts can be higher than 300° C. but lower than 600° C., and an annealing time, for annealing the n-type ohmic contacts, can be no longer than 10 minutes, for example.

The roughened portion can be an etched surface and the n-type ohmic contact on the etched surface can be formed into thin metal stripes. The n-type ohmic contacts on the planar surfaces can be wire-bonding pads.

The present invention further discloses a III-nitride based optoelectronic or electronic device, comprising one or more n-type ohmic contacts formed on a surface of an n-type III-nitride layer in a device, wherein the device is III-nitride based, the surface is a III-nitride surface, the surface includes at least a roughened portion, and the roughened portion is a roughened Nitrogen rich (N-rich) face of the III-nitride surface.

### BRIEF DESCRIPTION OF THE DRAWINGS

Referring now to the drawings in which like reference numbers represent corresponding parts throughout:

FIG. 1 is a cross-sectional schematic of current paths in a lateral LED.

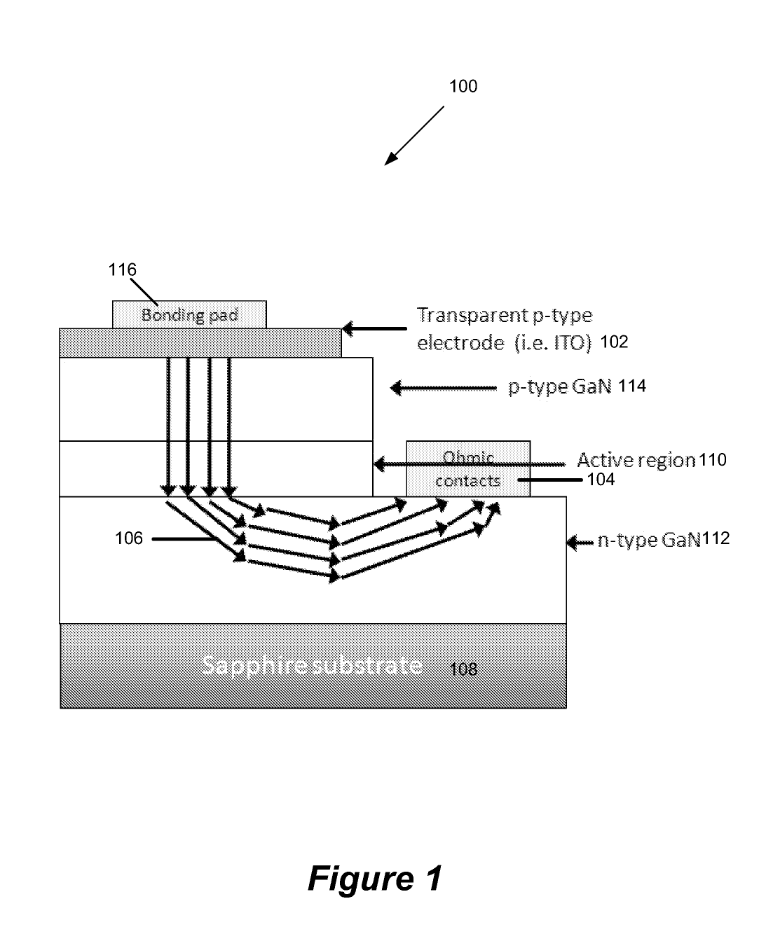

FIGS. 2(a)-(b) schematically illustrate a laser lift-off process, wherein the high power density of laser that has the wavelength transparent to a sapphire, but is strongly absorbed at the interface by GaN, can create enough thermal energy to break the bonds at the interface.

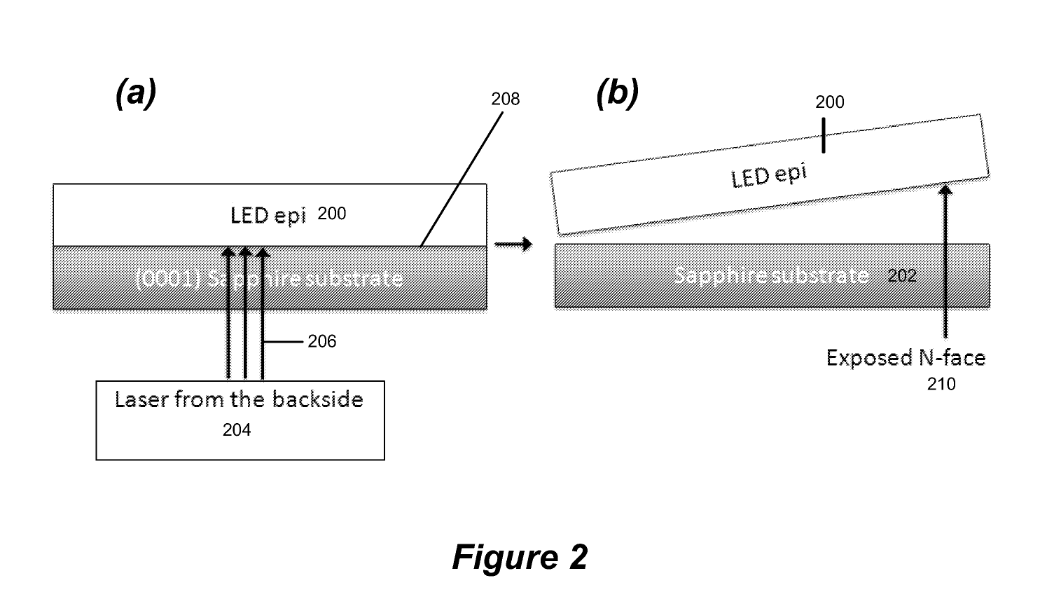

FIG. 3 is a schematic cross section of a vertical LED showing current path from n-type GaN to p-GaN (indicated by arrows within the LED).

FIG. 4 shows annealing temperature (degrees Celsius, ° C.) dependence of specific contact resistance (ohms times centimeter square, Ω*cm⁻²) for Ga-face and N-face GaN.

FIGS. 5(a)-(d) show brightness mapping of the light emission from N-face GaN for varying driving currents, wherein (a) shows light emission for a drive current of 20-50 milliamps (mA), (b) shows light emission for a drive current of 100 mA, (c) shows light emission for a drive current of 500 mA, and (d) shows light emission for a drive current of 1 Amp (A).

FIG. 6 shows surface morphology of (a) N-face n-type GaN after an LLO process, and, wherein the scale is 200 nanometers (nm) (b) the N-face n-type GaN of (a) after photoelectrochemical (PEC) etching.

FIG. 7 is a flowchart summarizing a fabrication process of present invention, starting from an LED epitaxial layer grown on a c-plane sapphire substrate.

FIG. 8 shows specific contact resistance of an n-type electrode on photoelectrochemically (PEC) etched N-face GaN, as compared to n-type electrodes on Ga-face and non-etched N-face.

FIG. 9 is a schematic drawing of (a) cross section view and (b) bottom view, of a vertical LED, illustrating the design of the enhanced current spreading method utilizing differential contact resistance between two n-type electrodes.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

A purpose of the present invention is to improve the current spreading for nitrogen-face (N-face) and N-face like (Al, In, Ga)N, together with lower ohmic contact resistance in the n-type electrode, without a decrease in the light extraction efficiency. The present invention has observed the lowering of the contact resistance after PEC etching of the N-face GaN surface.

Nomenclature

GaN and its ternary and quaternary compounds incorporating aluminum and indium (AlGaN, InGaN, AlInGaN) are commonly referred to using the terms (Al, Ga, In)N, III-nitride, Group III-nitride, nitride, Al_{(1-x-y)}In_{y}GaₓN where 0≦x≦1 and 0≦y≦1, or AlInGaN, as used herein. All these terms are intended to be equivalent and broadly construed to include respective nitrides of the single species, Al, Ga, and In, as well as binary, ternary and quaternary compositions of such Group III metal species. Accordingly, these terms comprehend the compounds AlN, GaN, and InN, as well as the ternary compounds AlGaN, GaInN, and AlInN, and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga, Al, In) component species that are present in the composition), can be employed within the broad scope of the invention. Accordingly, it will be appreciated that the discussion of the invention hereinafter in primary reference to GaN materials is applicable to the formation of various other (Al, Ga, In)N material species. Further, (Al, Ga, In)N materials within the scope of the invention may further include minor quantities of dopants and/or other impurity or inclusional materials. Boron (B) may also be included.

One approach to eliminating the spontaneous and piezoelectric polarization effects in GaN or III-nitride based optoelectronic devices is to grow the III-nitride devices on nonpolar planes of the crystal. Such planes contain equal numbers of Ga (or group III atoms) and N atoms and are charge-neutral. Furthermore, subsequent nonpolar layers are equivalent to one another so the bulk crystal will not be polarized along the growth direction. Two such families of symmetry-equivalent nonpolar planes in GaN are the {11-20} family, known collectively as a-planes, and the {1-100} family, known collectively as m-planes. Thus, nonpolar III-nitride is grown along a direction perpendicular to the (0001) c-axis of the III-nitride crystal.

Another approach to reducing polarization effects in (Ga, Al, In, B)N devices is to grow the devices on semi-polar planes of the crystal. The term “semi-polar plane” (also referred to as “semipolar plane”) can be used to refer to any plane that cannot be classified as c-plane, a-plane, or m-plane. In crystallographic terms, a semi-polar plane may include any plane that has at least two nonzero h, i, or k Miller indices and a nonzero 1 Miller index.

Some commonly observed examples of semi-polar planes include the (11-22), (10-11), and (10-13) planes. Other examples of semi-polar planes in the wurtzite crystal structure include, but are not limited to, (10-12), (20-21), and (10-14). The nitride crystal's polarization vector lies neither within such planes or normal to such planes, but rather lies at some angle inclined relative to the plane's surface normal. For example, the (10-11) and (10-13) planes are at 62.98° and 32.06° to the c-plane, respectively. The Gallium or Ga face of GaN is the c⁺ or (0001) plane, and the Nitrogen or N-face of GaN or a III-nitride layer is the c⁻ or (000-1) plane.

Technical Description

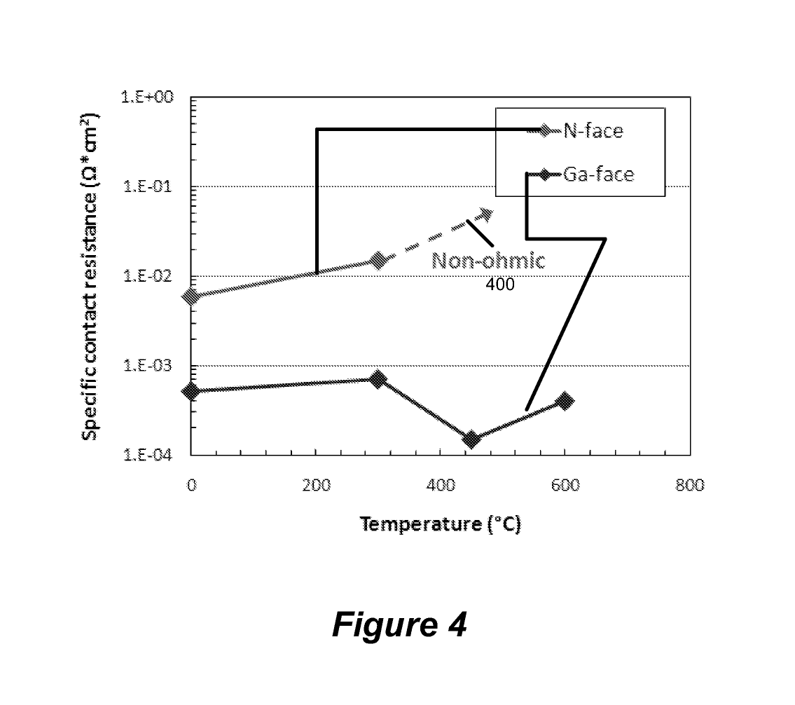

The present invention's study shows that the difference in ohmic contact resistance between the N-face and the Ga-face is about an order of magnitude, as illustrated in FIG. 4. Ga face shows a contact resistance of 1.5×10⁻⁴ Ωm², whereas the N-face has a contact resistance of about 1.5×10⁻² Ωcm² at best, and is non-ohmic 400 for annealing temperatures above 240° C. Due to the higher contact resistance, current spreading becomes worse.

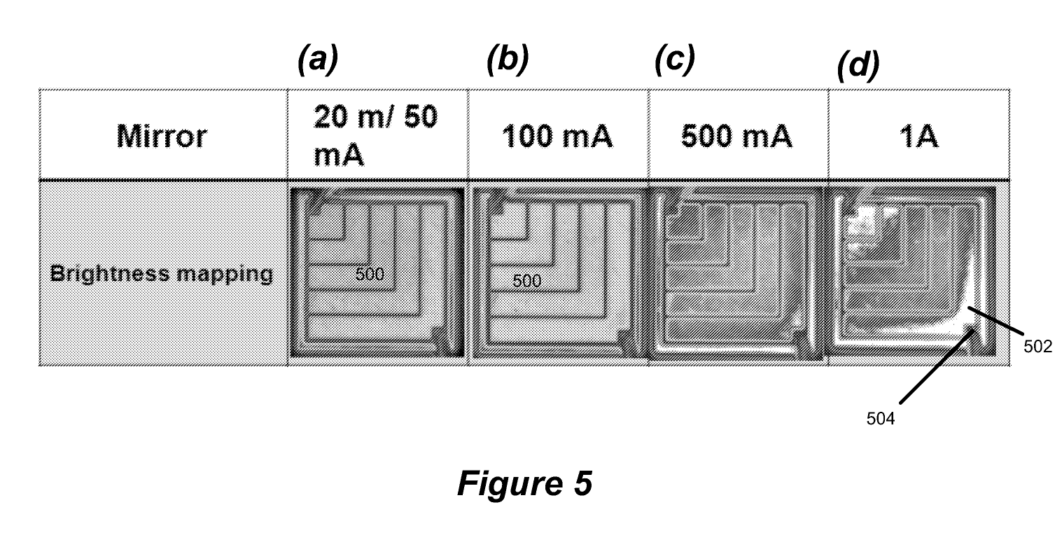

Mapping of the brightness on an N-face GaN electrode is shown in FIG. 5. Under low injection current (FIGS. 5(a)-(b)), the emission 500 is uniform, but brightness 502 increases around the probes 504 with increasing current, suggesting current crowding at a higher injection level of 1 ampere (FIG. 5(d)).

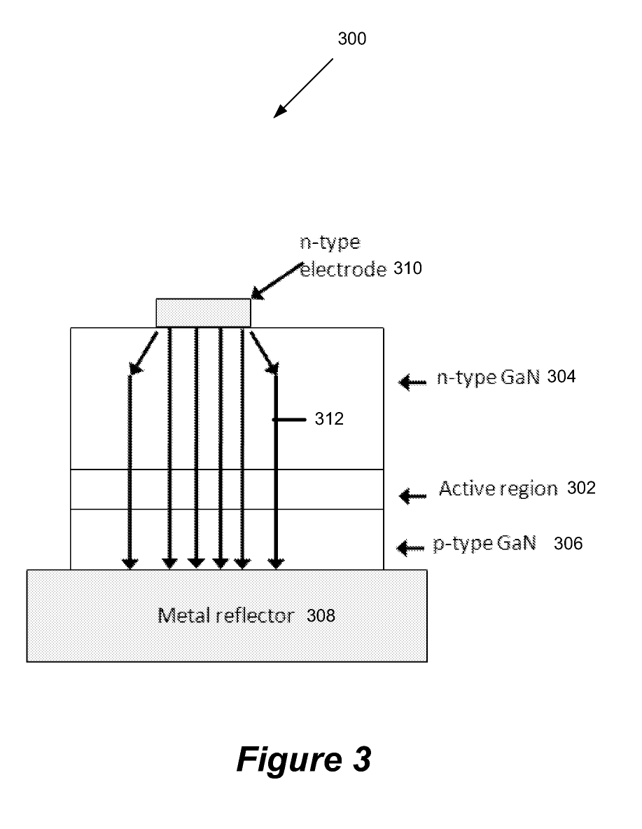

Another advantage of a vertical LED is the higher extraction efficiency, because a semi-transparent p-type electrode is no longer needed. P-type electrodes can be replaced with a metal reflector 308 (see FIG. 3), which is also an excellent thermal conductor.

In addition, it has been shown that photoelectrochemical (PEC) etching of N-face GaN, with the appropriate etching conditions, can produce a hexagonal pyramid surface with {10-1-1}crystallographic plane facets [5]. PEC etching is a photo-assisted wet etching technique with an above-bandgap light source and an electrochemical cell, where the semiconductor acts as the anode, and the contacting metal acts as the cathodes [6]. By surface roughening, the extraction efficiency can be enhanced [7].

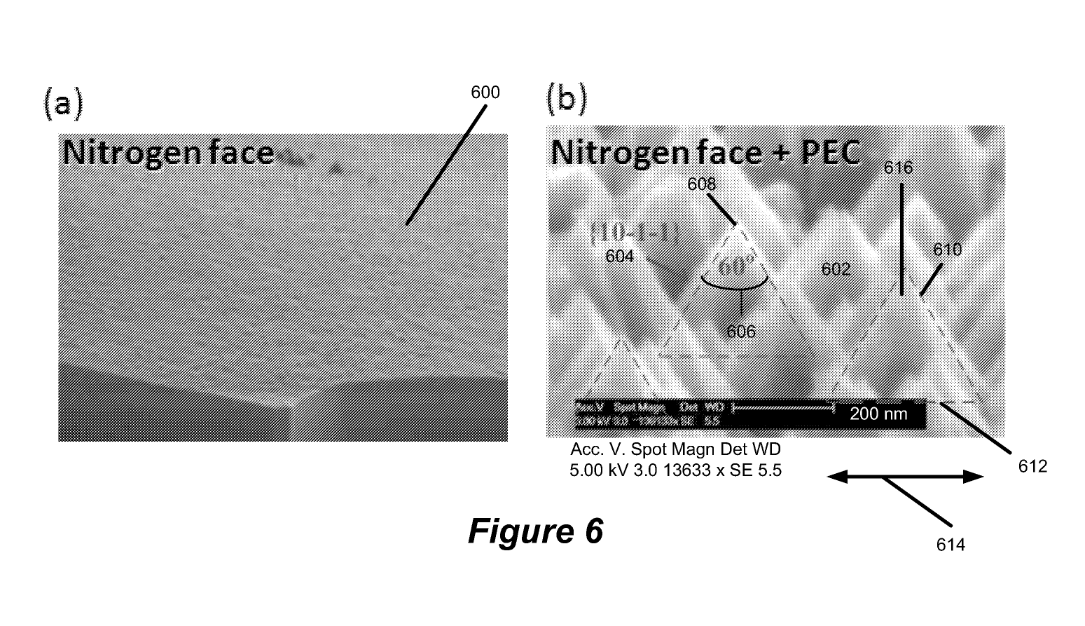

The surface morphology before and after PEC etching is shown in FIGS. 6(a)-(b). FIG. 6(a) shows the N-face surface 600 of an n-type GaN after an LLO process. FIG. 6(b) illustrates the PEC etched N-face n-type GaN surface comprises hexagonal pyramids 602 having sidewalls 604 that are {10-11} oriented facets of GaN and an angle 606 of 60 degrees (60°) between sidewalls 604 at the apex 608 of the pyramid 602 (the triangular cross-section of the pyramid 600 is indicated by the triangular dashed outline 610).

The present invention describes a method to circumvent the high contact resistance of an n-type electrode on N-face GaN, by utilizing a PEC surface roughening technique.

Process Steps

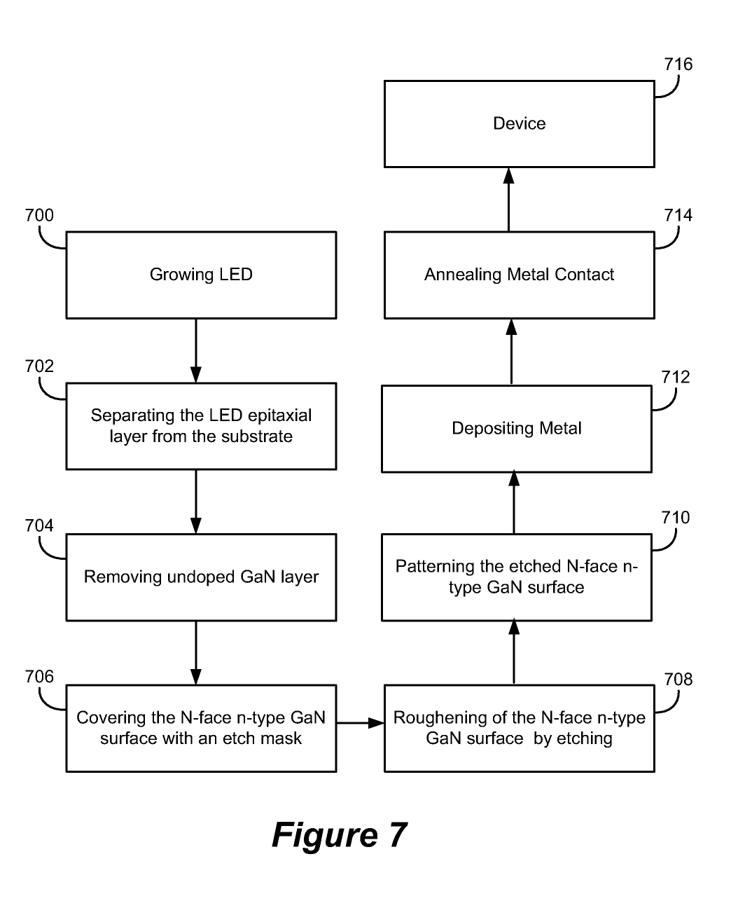

FIG. 7 summarizes the fabrication process, including the fabrication process of the N-face contact.

First, as represented in Block 700, the LEDs are epitaxially grown (e.g., on a c-plane sapphire substrate by MOCVD or MBE).

Next, to fabricate the vertical LEDs, the LED epitaxial layer is separated from the substrate (e.g., a sapphire substrate) by using the LLO process, as represented in Block 702.

Following the LLO process of Block 702, an undoped GaN layer is removed from the LED epitaxial layer (e.g., by dry-etching) to expose the n-GaN layer of the LED epitaxial layer, as represented in Block 704.

Then, a part of the N-face n-GaN surface is covered using a typical photolithography process, as represented in Block 706. Thus, an etch mask comprising photoresist is formed, forming areas of the N-face n-GaN surface that are covered and uncovered by photoresist. However, dielectric materials, such as SiO₂ and SiN, can be used as an etch mask as well.

After the covering step, the uncovered area of the N-face surface is etched (e.g., by a wet etching, such as PEC process), and the uncovered area of the N-face surface becomes rough, as represented in Block 708.

After the etching, the mask is removed. The N-face surface is then patterned with a photoresist for metal deposition (e.g., n-type electrode patterning by photolithography), as represented in Block 710.

Metal is then deposited, as represented in Block 712, e.g., using an electron beam evaporator. For example, an Aluminum-based metal stack can be deposited by an electron beam evaporator. The metal stack is deposited on both the roughened and planar surfaces of the N-face n-GaN. After the deposition, the metal contacts are annealed under N₂ ambient for more than 2 minutes, as represented in Block 714. The annealing temperature is between 300° C. and 700° C., for example. In one or more examples, the n-type ohmic contacts comprise metal and an annealing temperature of the n-type ohmic contacts is higher than 300° C. but lower than 600° C., and an annealing time, for annealing the n-type ohmic contacts, is no longer than 10 minutes.

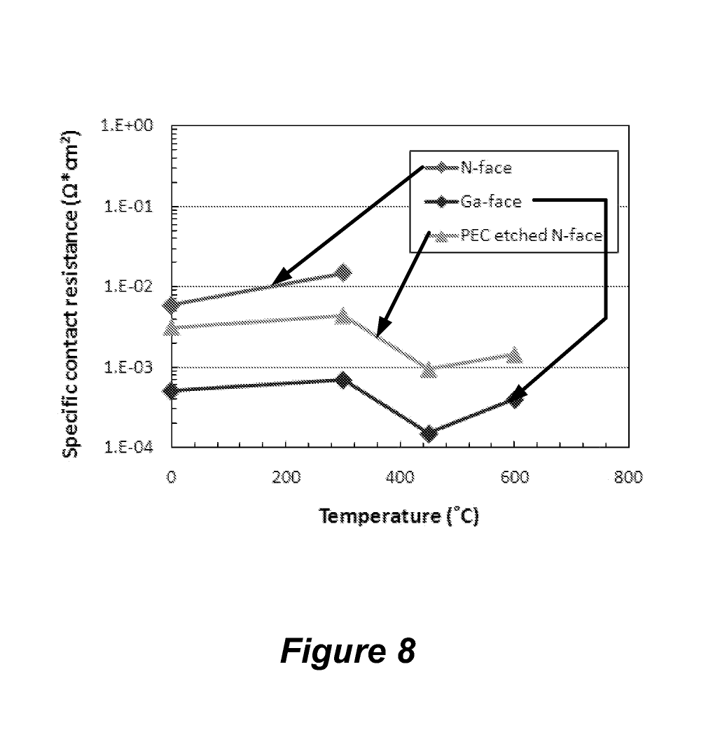

The {10-1-1} plane of the N-face GaN (resulting from the etching) is a Ga-like surface where there are more Ga atoms than N atoms on the surface. Thus, the lower contact resistance may be attributed to the ohmic contacts formed on the exposed {10-1-1}. In addition, the effective total contact area is also larger than the same contact size on the planar surface, leading to a lower contact resistance as well. As a result, overall reduction of contact resistance is observed, as shown in FIG. 8.

When the electrodes on the roughened and planar surface are connected, the current flows to the lower contact resistance region. Narrow bar type contacts which minimize the absorption of the emitted light, and low contact resistance, can improve the current spreading without losing the light extraction efficiency.

Block 716 represents the end result of the method, a device such as a vertical light emitting diode.

Steps may be added or omitted as desired.

Device Structure

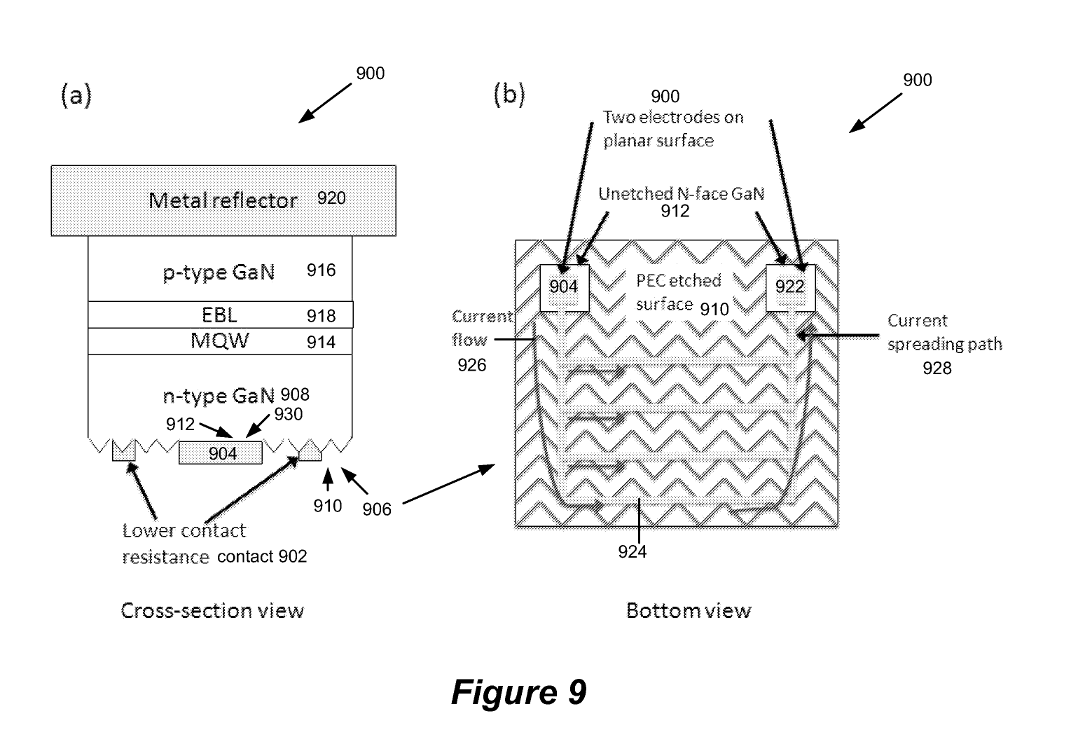

FIGS. 9(a) and 9(b) shows a schematic drawing of the device 900 and the N-face surface after the process of FIG. 7 described above.

FIG. 9(a) illustrates a III-nitride or (Al, In, Ga)N based optoelectronic device 900 (a vertical light emitting diode), comprising one or more n-type ohmic contacts 902, 904 formed on/to one or more III-nitride surfaces 906 of an n-type (Al, In, Ga)N layer (n-type GaN layer 908) in the device 900. The surface 906 includes one or more roughened portions 910, wherein each of the roughened portions 910 is a roughened Nitrogen rich (N-rich) face of the (Al, In, Ga)N layer 908.

An N-rich face of the layer 908 is roughened to form the roughened portion 910. The N-rich face can be a semipolar or nonpolar plane of the III-nitride layer 908 comprising at least as much nitrogen as a group III element (e.g., the N-rich face can contain as at least as many nitrogen atoms as group III atoms such as gallium). For example, the N-rich semipolar plane can be, but is not limited to, a (10-12), (11-22), or (10-11) semi-polar plane. The N-rich face can also be a Nitrogen-face of the III-nitride layer 908, for example.

FIG. 6 illustrates that the roughened portion 910 can comprise one or more structures (e.g., pyramids 602) on the surface 906 having a width 612 at a base 614 of the structures that is larger than a width at a top 616 of the structures. The roughened portion can be roughened such that the structures have a height and a base width of 200 nanometers or more. The roughened portion can be roughened such that a density of the structures on the surface 906 is at least 3 structures per 200 nanometers or micrometers square, or at least as dense and as rough as illustrated in FIG. 6. The roughening with structures can cover (e.g., uniformly and/or predominantly, or substantially) an entirety or a portion 910 of the surface 906.

The shape of the structures/roughening is not limited. For example, roughening can be such that the structures, features, or texture include, but are not limited to, islands, protrusions from a growth plane, facetted structures, pyramids, structures having a triangular or trapezoidal cross-section, conical shapes, structures with sidewalls inclined towards each other to form a peak or taper, or structures having straight or curved sidewalls.

FIG. 8 illustrates that the roughened portion 910 can be roughened such that a contact resistance for the n-type ohmic contact 902 on the roughened portion 910 is reduced, e.g., reduced to 1×10⁻³ ohm centimeters squared or less, reduced to no more than 1×10⁻³ ohm centimeters squared, or reduced to a value less than or equal to a contact resistance for an n-type ohmic contact on a Gallium face (Ga-face) of a similar III-nitride layer. For example, the roughened portion 910 can be roughened such that an n-type ohmic contact is formed (e.g., without the roughening, a non-ohmic n-type contact would be formed).

FIG. 9(a) also illustrates the surface 906 can further include one or more non-roughened (e.g., planar) portions 912, wherein each of the non-roughened portions 912 is an N-rich face of the (Al, In, Ga)N layer 908. Accordingly, in this embodiment, only selected regions 910 of the surfaces 906 are roughened by e.g., a photoelectrochemical etching technique or a dry-etching technique, for example. In this manner, one or more ohmic contacts 902, 904 can be formed on both a roughened surface 910 and a planar surface 912 of an N-rich face or N-face of the n-type (Al, In, Ga)N 908. A contact resistance is lower for the ohmic contacts 902 on the roughened surfaces 910.

As shown in FIG. 9(a), the vertical LED comprises a light emitting active layer 914 (e.g., multi quantum well, MQW, or indium containing layer, such as an InGaN quantum well with GaN barriers), wherein the active layer 914 is between a p-type GaN layer 916 and the n-type GaN layer 908. An electron blocking layer 918 (e.g., AlGaN) is between the active layer 914 and the p-type GaN layer 916. The p-type GaN layer 916 is on or above a metal reflector 920.

FIG. 9(b) is a bottom view of the surface 906 including the roughened portion 910 (e.g., PEC etched surface) and the non-roughened (e.g., planar) portions 912. The n-type ohmic contacts 902, 904, 922 are formed on both the roughened portion 910 (contact 902) and the non-roughened portion 912 (contacts 904, 922). The contact resistance is lower for the n-type ohmic contact 902 on the roughened portion 910 as compared to a contact resistance for the n-type ohmic contacts 904, 922 on the non-roughened portions 912.

FIG. 9(b) also illustrates the ohmic contacts 902 on the etched surfaces are formed into thin metal stripes 924, and the ohmic contacts 904, 922 on the planar surfaces 912 are wire-bonding pads 904, 922. Also shown in FIG. 9(b) is the current flow, indicated by arrows 926, and the current spreading path 928. The roughened portion 910 can be roughened such that a current spreading in the n-type layer 908 is increased. Metal alloys can be used to form the n-type ohmic contacts 902, 904, 922.

The number and roughening of the roughened portions 910 can be such that light emitted by the light emitting device 900 has uniform emission, with no significant increase in the light emission at a location 504 (see FIG. 5) where drive current is injected into, or voltage is applied to, the device 900. The uniform light emission can be for the drive current of 500 milliamps or greater, or 1 amp or greater.

As described in the previous section, the present invention can enhance the current spreading in an N-face GaN ohmic contact for a vertical structure LED. Some semipolar plane LEDs having the surface closer or similar to N-face GaN may also benefit from this invention.

An operating voltage of the LED can be reduced due to a reduced contact resistance of the ohmic contacts. An external quantum efficiency of the LED can be increased due to enhanced current spreading in the n-type (Al, In, Ga)N.

Accordingly, FIGS. 7, 8 and 9(a)-(b) illustrate a method of fabricating an (Al, In, Ga)N based optoelectronic device 900, comprising forming one or more n-type ohmic contacts 902, 904 on one or more (Al, In, Ga)N surfaces 906 of the device 900, wherein each of the surfaces 906 comprise an Nitrogen face (N-face) and/or a N-rich face of the (Al, In, Ga)N 908, the n-type contacts 902, 904 are on the N-face and/or the N-rich face, and a current spreading of the n-type ohmic contacts 902, 904 is enhanced by a combination of a lower and a higher contact resistance on the surfaces 906. The method can comprise forming the one or more n-type ohmic contacts 902, 904 on one or more surfaces 930 comprising one or more N-rich semipolar planes or an N-face of the device, wherein the semipolar planes are (10-12), (11-22), and/or (10-11) planes.

Advantages and Improvements

Conventional vertical LEDs suffer from higher contact resistance, resulting in poor current spreading on N-face GaN. A current spreading layer such as indium doped tin oxide is also used as a current spreading layer on N-face GaN, but it still suffers from high contact resistance.

However, as shown in FIG. 8, the contact resistance dramatically drops for ohmic contacts on PEC etched surface, as compared to the ohmic contact on N-face GaN, even at the annealing temperature of 450° C.

The present invention utilizes both high contact resistance and low contact resistance ohmic contacts to enhance the current spreading. A finger-like contact design is also possible, due to the low contact resistance, which improves the efficiency of LEDs by lowering the operating voltage.

Thus, the present invention can reduce the series resistance of an LED by lowering the contact resistance. At the same time, the present invention allows better current spreading with the same surface coverage of the metal contacts. Therefore, the light extraction efficiency can be higher as compared to a normal vertical LED.

The present invention can also allow the manufacture of LEDs with higher efficiency, without increasing the cost, as the manufacturing process is solely based on existing techniques. Therefore, products in which LEDs are required can be provided with a lower price and better performance.

Possible Modifications

The present invention is not limited to PEC etching. Roughening of N-face, or other crystallographic planes, can also be achieved by a dry-etching technique. With a dry etching technique, it is easier to control the density and size of each resulting cone on the etched surface. Also, the resulting cones are more uniformly distributed, which can also improve the light extraction even further.

The surface 930 that is etched or roughened to form the n-type ohmic contact is not limited to a particular crystal plane. The surface can be a semipolar or nonpolar plane, for example. The roughening may also be applied to the fabrication of p-type ohmic contacts.

Mask design for the metal contact can also be optimized to maximize the current spreading and minimize the surface coverage.

The present invention can be applied to the fabrication of any optoelectronic and electronic devices, including Light Emitting Diodes (LEDs), laser diodes, solar cells, transistors, and high electron mobility transistors, for example.

### REFERENCES

The following references are incorporated by reference herein.
[1] S, Nakamura, M. Senoh, N. Iwasa, S, Nagahama, T. Yamada, and T. Mukai, Jpn. J. Appl. Phys. 34, L1332 (1995).
[2] B. P. Luther, S. E. Mohney, T. N. Jackson, M. Asif Khan, Q. Chen, and J. W. Yang, Appl. Phys. Lett. 70, 57 (1997).
[3] J. S. Kwak, K. Y. Lee, J. Y. Han, J. Cho, S. Chae, O. H. Nam, and Y. Park, Appl. Phys. Lett. 79, 3254 (2001).
[4] H. Kim, J. -H. Ryou, R. D. Dupuis, S. -N. Lee, Y. Park, J. -W. Jeon, and T. Y. Seong, App. Phys. Lett. 93, 192106 (2008).
[5] Y. Gao, T. Fujii, R. Sharma, K. Fujito, S. P. DenBaars, S, Nakamura, and E. L. Hu, Jpns. J. App. Phys. 43, L637 (2004).
[6] M. S. Minsky, M. White, and E. L. Hu, Appl. Phys. Lett. 68, 1531 (1996).
[7] Y. Gao, M. D. Craven, J. S. Speck, S. P. DenBaars, and E. L. Hu, Appl. Phys. Lett. 84, 3322 (2004).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of fabricating a III-nitride based optoelectronic or electronic device, comprising:
forming one or more n-type ohmic contacts to a surface of an n-type III-nitride layer in a device, wherein:
the device is III-nitride based,
the surface is a III-nitride surface,
the surface includes at least a roughened portion, and
the roughened portion is a roughened portion of a Nitrogen rich (N-rich) face of the III-nitride surface.

2. The method of claim 1, wherein:
the surface includes the roughened portion and at least a non-roughened (planar) portion of the N-rich face,
the n-type ohmic contacts are formed on both the roughened portion and the non-roughened portion, and
a contact resistance is lower for the n-type ohmic contacts on the roughened portion as compared to a contact resistance for the n-type ohmic contacts on the non-roughened portion.

3. The method of claim 1, wherein the roughened portion is roughened such that a current spreading in the n-type layer is increased.

4. The method of claim 1, wherein the roughened portion is roughened such that a contact resistance for the n-type ohmic contact on the roughened portion is reduced.

5. The method of claim 4, wherein the contact resistance is reduced to 1×10⁻³ ohm centimeters squared or less.

6. The method of claim 4, wherein the contact resistance is reduced to a value less than or equal to a contact resistance for an n-type ohmic contact on a Gallium face (Ga-face) of a similar III-nitride layer.

7. The method of claim 1, wherein:
the device is a light emitting diode (LED), and
emission of light from the LED is uniform, with no significant increase in the emission at one or more locations for injecting drive current into the LED, for the drive current to the device of 500 milliamps or greater, or 1 amp or greater.

8. The method of claim 2, wherein the N-rich face is a semipolar plane of the III-nitride layer comprising at least as much nitrogen as a group III element.

9. The method of claim 8, wherein the semipolar plane is a (10-12), (11-22), or (10-11) semi-polar plane.

10. The method of claim 2, wherein the N-rich face is a Nitrogen-face of the III-nitride layer.

11. The method of claim 1, wherein the roughened portion is roughened by a photoelectrochemical etching or dry etching technique.

12. The method of claim 1, wherein the n-type ohmic contacts comprise metal and an annealing temperature of the n-type ohmic contacts is higher than 300° C. but lower than 600° C.

13. The method of claim 12, wherein an annealing time, for annealing the n-type ohmic contacts, is no longer than 10 minutes.

14. The method of claim 1, wherein the device is a vertical light emitting diode.

15. The method of claim 2, wherein:
the roughened portion is an etched surface and the n-type ohmic contact on the etched surface is formed into thin metal stripes, and
the n-type ohmic contact on the non-roughened portion is a wire-bonding pad.

16. A III-nitride based optoelectronic or electronic device, comprising:
one or more n-type ohmic contacts formed on a surface of an n-type III-nitride layer in a device, wherein:
the device is III-nitride based,
the surface is a III-nitride surface,
the surface includes at least a roughened portion, and
the roughened portion is a roughened portion of a Nitrogen rich (N-rich) face of the III-nitride surface.

17. The device of claim 16, wherein:
the surface includes the roughened portion and at least a non-roughened (planar) portion of the N-rich face,
the n-type ohmic contacts are formed on both the roughened portion and the non-roughened portion, and
a contact resistance is lower for the n-type ohmic contact on the roughened portion as compared to a contact resistance for the n-type ohmic contact on the non-roughened portion.

18. The device of claim 16, wherein the roughened portion is roughened such that a current spreading in the n-type layer is increased.

19. The device of claim 16, wherein the roughened portion is roughened such that a contact resistance for the n-type ohmic contact on the roughened portion is reduced.

20. The device of claim 19, wherein the contact resistance is reduced to 1×10⁻³ ohm centimeters squared or less.

21. The device of claim 19, wherein the contact resistance is reduced to a value less than or equal to a contact resistance for an n-type ohmic contact on a Gallium face (Ga-face) of a similar III-nitride layer.

22. The device of claim 16, wherein:
the device is a light emitting diode, and
emission of light from the LED is uniform, with no significant increase in the emission at one or more locations for injecting drive current into the device, for the drive current to the device of 500 milliamps or greater, or 1 amp or greater.

23. The device of claim 17, wherein the N-rich face is a semipolar plane of the III-nitride layer comprising at least as much nitrogen as a group III element.

24. The device of claim 23, wherein the semipolar plane is a (10-12), (11-22), or (10-11) semi-polar plane.

25. The device of claim 17, wherein the N-rich face is a Nitrogen-face of the III-nitride layer.

26. The device of claim 16, wherein the device is a vertical light emitting diode.

27. The device of claim 17, wherein:
the roughened portion is an etched surface and the n-type ohmic contact on the etched surface is formed into thin metal stripes, and
the n-type ohmic contact on the non-roughened portion is a wire-bonding pad.
